(19) United States
(12) Patent Application Publication
(10) Pub. No.: US 2016/0104602 A1
(43) Pub. Date: Apr. 14, 2016

(54) SEMICONDUCTOR MANUFACTURING APPARATUS, SEMICONDUCTOR MANUFACTURING METHOD, AND FLOW RATE ADJUSTING MECHANISM

(71) Applicant: Kabushiki Kaisha Toshiba, Minato-ku (JP)

(72) Inventor: Daisuke TOKIWA, Yokkaichi (JP)

(73) Assignee: Kabushiki Kaisha Toshiba, Minato-ku (JP)

(21) Appl. No.: 14/616,114

(22) Filed: Feb. 6, 2015

(30) Foreign Application Priority Data
Oct. 10, 2014 (JP) 2014-209196

(51) Int. Cl. H01J 37/32; H01L 21/67; H01L 21/3065

(52) U.S. Cl. CPC H01J 37/32449; H01L 21/3065; H01L 21/67069; H01J 2237/334

(57) ABSTRACT

According to one embodiment, a semiconductor manufacturing apparatus includes a chamber, a substrate support part, a gas supply part, an exhaust port, and a flow rate adjustment part. The gas supply part is configured to supply a gas into a process space above the substrate. The exhaust port is configured to exhaust a gas, which is present inside the chamber, from the chamber. The flow rate adjustment part is provided inside the chamber. The flow rate adjustment part is configured to adjust a flow rate of a gas flowing from the process space to the exhaust port. The flow rate adjustment part is configured to adjust a gas flow rate in two or more different directions in parallel with a surface of the substrate. Amounts of adjustment of the flow rate in each of the directions are different.

### CROSS-REFERENCE TO RELATED APPLICATIONS

This application is based upon and claims the benefit of priority from Japanese Patent Application No. 2014-209196, filed on Oct. 10, 2014; the entire contents of which are incorporated herein by reference.

### FIELD

Embodiments described herein relate generally to a semiconductor manufacturing apparatus, semiconductor manufacturing method, and flow rate adjusting mechanism.

### BACKGROUND

A plasma processing apparatus, which is one of the semiconductor manufacturing apparatuses, serves to perform a plasma process to a substrate as a processing object. The plasma processing apparatus is configured to supply a gas into a chamber and generate its plasma. In the plasma processing apparatus, there is a case where the flow rate of the gas becomes uneven in a two-dimensional direction in parallel with the surface of the substrate. If the gas flow rate is uneven, the process comes to make progress with different rates on the surface of the substrate. In this case, it becomes difficult to uniformly process the substrate.

### BRIEF DESCRIPTION OF THE DRAWINGS

FIG. 1 is a view schematically showing a configuration of a semiconductor manufacturing apparatus according to a first embodiment;

FIG. 2 is a view showing an upper surface configuration of a ring member shown in FIG. 1;

FIG. 3 is a view showing a perspective configuration of the ring member shown in FIG. 1;

FIG. 4 is a view showing a partially sectional configuration of the ring member shown in FIGS. 2 and 3;

FIG. 5 is a view showing an example of the relationship between a position on a wafer and an etching rate, before adjustment of a gap width by respective portions of the ring member shown in FIGS. 2 and 3;

FIG. 6 is a view schematically showing a configuration of a semiconductor manufacturing apparatus according to a second embodiment;

FIG. 7 is a view showing a plan view configuration of a circular disc member shown in FIG. 6; and

FIG. 8 is a view for explaining a movement manner of the circular disc member shown in FIG. 7.

### DETAILED DESCRIPTION

In general, according to one embodiment, a semiconductor manufacturing apparatus includes a chamber, a substrate support part, a gas supply part, an exhaust port, and a flow rate adjustment part. The substrate support part is provided inside the chamber. The substrate support part is configured to support a substrate. The substrate is a processing object. The gas supply part is configured to supply a gas into a process space above the substrate. The exhaust port is configured to exhaust a gas, which is present inside the chamber, from the chamber. The flow rate adjustment part is provided inside the chamber. The flow rate adjustment part is configured to adjust a flow rate of a gas flowing from the process space to the exhaust port. The flow rate adjustment part is configured to adjust a gas flow rate in two or more different directions in parallel with a surface of the substrate. Amounts of adjustment of the flow rate in each of the directions are different.

Exemplary embodiments of a semiconductor manufacturing apparatus, semiconductor manufacturing method, and flow rate adjusting mechanism will be explained below in detail with reference to the accompanying drawings. The present invention is not limited to the following embodiments.

### First Embodiment

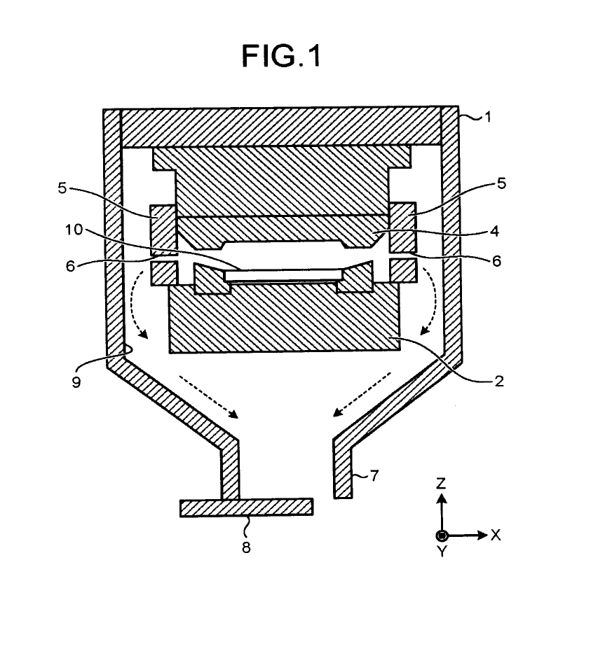

FIG. 1 is a view schematically showing a configuration of a semiconductor manufacturing apparatus according to a first embodiment. This semiconductor manufacturing apparatus is a plasma processing apparatus for performing a plasma process to a wafer 10 made of a semiconductor substrate. The plasma processing apparatus may be an etching apparatus, CVD apparatus, or sputtering apparatus. The plasma processing apparatus may be used for performing thin film formation or pattern formation on the wafer 10. In the following explanation, the plasma processing apparatus is supposed to be an etching apparatus for performing dry etching to the wafer 10.

A chamber 1 is provided to form an airtight space in which a plasma process is performed. A substrate support part 2 is provided inside the chamber 1. The substrate support part 2 includes an electrostatic chuck mechanism (not shown) for attracting the wafer 10 as a processing object by an electrostatic force. The substrate support part 2 is configured to support the wafer 10 in a horizontal state. The substrate support part 2 serves as a lower electrode.

Here, an X-direction and a Y-direction are defined by two directions in parallel with the surface of the wafer 10 facing a gas supply part 4. The X-axis of the X-direction and the Y-axis of the Y-direction are set to be perpendicular to each other. Further, a Z-axis is set to be perpendicular to the X-axis and the Y-axis. The Z-axis is an axis in parallel with the vertical direction. The X- and Y-directions are in parallel with the horizontal direction.

The gas supply part 4 is configured to supply a process gas used for the plasma process. The gas supply part 4 includes a showerhead. The showerhead has a number of holes for spouting the process gas toward the wafer 10. The gas supply part 4 is disposed at a position to face the wafer 10 supported on the substrate support part 2. The gas supply part 4 is configured to supply the process gas into a process space above the wafer 10. The gas supply part 4 serves as an upper electrode. The substrate support part 2 and the gas supply part 4 form a pair of parallel plate electrodes.

An exhaust port 7 is formed at the center of the bottom of the chamber 1. The exhaust port 7 is configured to exhaust the process gas from inside the chamber 1. The exhaust port 7 may be formed at any position of the chamber 1. The exhaust port 7 is equipped with an openable and closeable valve 8. The valve 8 can adjust the size of the opening area, through which the process gas passes, to adjust the pressure of the process gas inside the chamber 1.

The ring member 5 is attached to the lateral side of the gas supply part 4. The ring member 5 is an annular surrounding member that surrounds the periphery of the process space above the wafer 10 along its circumferential direction. The process space is surrounded by the gas supply part 4, the substrate support part 2, and the ring member 5. The ring member 5 is divided into an upper member as a first member and a lower member as a second member. The ring member 5 includes a gap 6 as a first gap, formed between the upper member and the lower member. The upper member is set in contact with the gas supply part 4. The lower member is set in contact with the substrate support part 2.

The process gas can pass through the gap 6 to flow from the process space above the wafer 10 to the outside of the process space. The ring member 5 can adjust the width of the gap 6 to adjust the pressure of the process gas inside the process space. The ring member 5 serves as a flow rate adjustment part provided inside the chamber 1. The ring member 5 constitutes a flow rate adjusting mechanism for adjusting the flow rate of the process gas flowing from the process space to the exhaust port 7.

The process gas can pass between the substrate support part 2 and the inner wall 9 of the chamber 1 to flow from the process space to the exhaust port 7. The plasma processing apparatus can control the flow of the process gas by adjusting the valve 8 and adjusting the width of the gap 6 of the ring member 5.

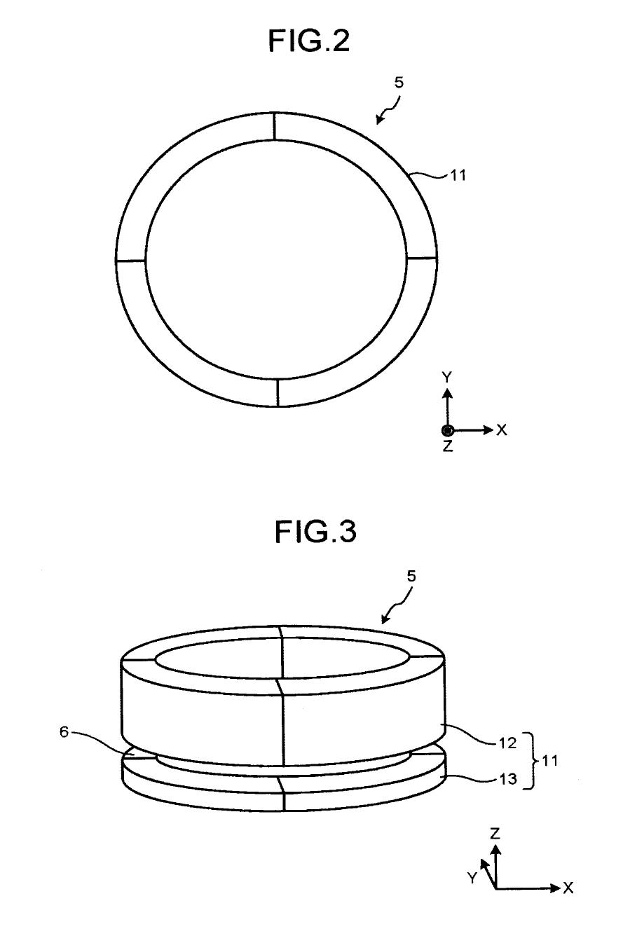

FIG. 2 is a view showing an upper surface configuration of a ring member shown in FIG. 1. FIG. 3 is a view showing a perspective configuration of the ring member shown in FIG. 1. The ring member 5 is divided into four portions 11 on the X-Y plane. Each of these portions 11 is further divided in the Z-direction in accordance with the upper member 12 and the lower member 13.

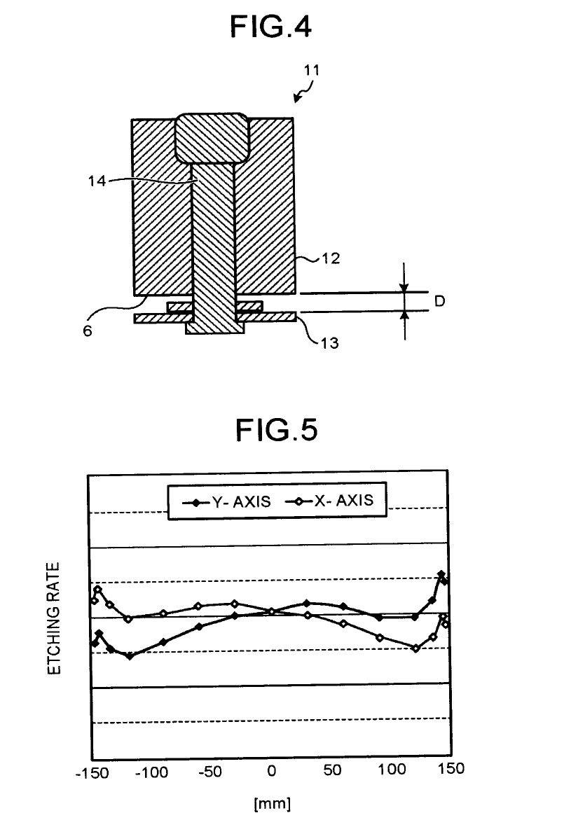

FIG. 4 is a view showing a partially sectional configuration of the ring member shown in FIGS. 2 and 3. The portions 11 described above are respectively equipped with height adjusting members 14 to adjust the positional relationship between the upper member 12 and the lower member 13 in the Z-direction. In the example shown in FIG. 4, the height adjusting members 14 can be extended and contracted to adjust the height of the upper member 12. The height of the upper member 12 is defined by the position of the upper member 12 in the Z-direction. The ring member 5 is configured such that each of the height adjusting members 14 can adjust the width D of the gap 6 by adjusting the height of the upper member 12. The portions 11 can individually adjust the positions of the respective parts of the upper member 12 in the Z-direction. Thus, the ring member 5 can individually adjust the respective widths D by adjusting the positions of the respective parts of the upper member 12 of the portions 11.

The ring member 5 can adjust the flow rate of the process gas all over the entirety of the wafer 10 by uniformly adjusting the widths D at the respective portions 11. Further, the ring member 5 can adjust the flow rate balance of the process gas in the X- and Y-directions by individually adjusting the widths D at the respective portions 11. Amounts of adjustment of the flow rate in each of the X- and Y-directions are different.

The height adjusting members 14 may be configured such that they raise the upper member 12 together with the lower member 13 after they once raise the upper member 12 until the width D become a preset maximum width. When the lower member 13 is moved upward, a gap is also formed between the ring member 5 and the substrate support part 2. The gap formed between the lower member 13 and the substrate support part 2 will be referred to as a second gap.

The process gas from the process space can pass through the gap 6 formed between the upper member 12 and the lower member 13 and the gap formed between the lower member 13 and the substrate support part 2. The ring member 5 can cause the portions 11 to individually adjust the respective widths of the gap between the lower member 13 and the substrate support part 2. The upper member 12 and the lower member 13 may be configured such that one of them is fixed and the other is movable up and down. Also in this case, it is possible to adjust the width of the gap 6 between the upper member 12 and the lower member 13 and the width of the gap between the lower member 13 and the substrate support part 2.

Here, the ring member 5 is not limited to the example divided into the four portions 11. The ring member 5 may have any structure, as long as it is divided into a plurality of portions 11 including at least a first portion and a second portion, along the circumferential direction of the process space. In this case, the first portion and the second portion allow the respective widths of the gap 6 to be individually adjusted. The ring member 5 may be divided into a plurality of portions 11 in the number other than four.

FIG. 5 is a view showing an example of the relationship between a position on a wafer and an etching rate, before adjustment of the gap width by the respective portions of the ring member shown in FIGS. 2 and 3. The vertical axis of the graph shown in FIG. 5 denotes an etching rate in an arbitrary unit. The horizontal axis of the graph denotes a position on the surface of the wafer 10 in the X-direction or the Y-direction. The position defined by X=0 mm and Y=0 mm is the position at the center of the wafer 10. In each of the X-direction and the Y-direction, a plus side and a minus side are preset.

In the example shown in FIG. 5, as regards the X-direction, the etching rate tends to decrease more prominently on the plus side of this direction from the center of the wafer 10. On the other hand, as regards the Y-direction, the etching rate tends to decrease more prominently on the minus side of this direction from the center of the wafer 10. If the etching rate becomes different in a two-dimensional direction, the plasma processing apparatus can hardly perform uniform etching over the wafer 10. As one of the factors that cause such a difference in the etching rate, there is a case where the flow rate of the process gas is uneven in the space above the wafer 10.

The ring member 5 can individually adjust the widths D corresponding to the respective portions 11. Thus, the plasma processing apparatus can adjust the flow rate at the respective portions 11 to reduce the unevenness in the flow rate of the process gas in a two-dimensional direction. In this respect, the portions 11 of the ring member 5 are used such that a portion 11 present in a direction in which the etching rate tends to be lower is operated to narrow the corresponding width D of the gap 6. When this width D is narrowed, the residence time of the process gas in the process space is correspondingly prolonged, and the etching progress is thereby promoted. In the example shown in FIG. 5, the widths D of the gap 6 are narrowed on the plus side of the X-direction and on the minus side of the Y-direction, where the etching rate tends to be lower.

The ring member 5 is not limited to one configured to adjust the flow rate of the process gas in the X-direction and the Y-direction. The ring member 5 may have any structure as long as it can adjust the gas flow rate in two or more different directions in parallel with the surface of the wafer 10.

According to the first embodiment, the semiconductor manufacturing apparatus is configured to individually adjust the widths of the gap 6 at the respective portions 11 of the ring member 5. The ring member 5 can adjust the gas flow rate in two or more different directions in parallel with the surface of the wafer 10. Thus, the semiconductor manufacturing apparatus can make the gas flow rate uniform over the wafer 10 by adjusting the gas flow rate balance in two or more different directions in parallel with the surface of the wafer 10. Consequently, the semiconductor manufacturing apparatus can provide an effect of uniformly processing a processing object.

### Second Embodiment

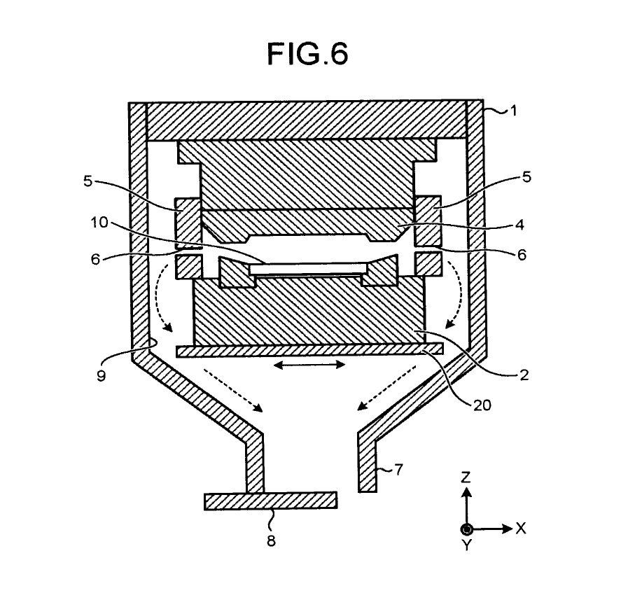

FIG. 6 is a view schematically showing a configuration of a semiconductor manufacturing apparatus according to a second embodiment. The constituent elements corresponding to those of the first embodiment described above are denoted by the same reference numerals, and their repetitive description will be suitably omitted. The semiconductor manufacturing apparatus according to the second embodiment is a plasma processing apparatus that includes a circular disc member 20.

The circular disc member 20 is a blocking member configured to partly close the opening area between the substrate support part 2 and the inner wall 9 of the chamber 1 around the substrate support part 2. The blocking member serves as a flow rate adjustment part provided inside the chamber 1. The blocking member constitutes a flow rate adjusting mechanism for adjusting the flow rate of the process gas flowing from the process space to the exhaust port 7. The circular disc member 20 is attached to the lower surface of the substrate support part 2.

The circular disc member 20 can form a gap through which the process gas passes to flow from the process space to the exhaust port 7. The circular disc member 20 is configured to form the gap between itself and the inner wall 9. The circular disc member 20 can be moved in the X- and Y-directions to adjust the width of the gap.

As in the first embodiment, the plasma processing apparatus can control the flow of the process gas by adjusting the valve 8 and adjusting the width of the gap 6 of the ring member 5. Further, the plasma processing apparatus can control the flow of the process gas by adjusting the width of the gap between the circular disc member 20 and the inner wall 9.

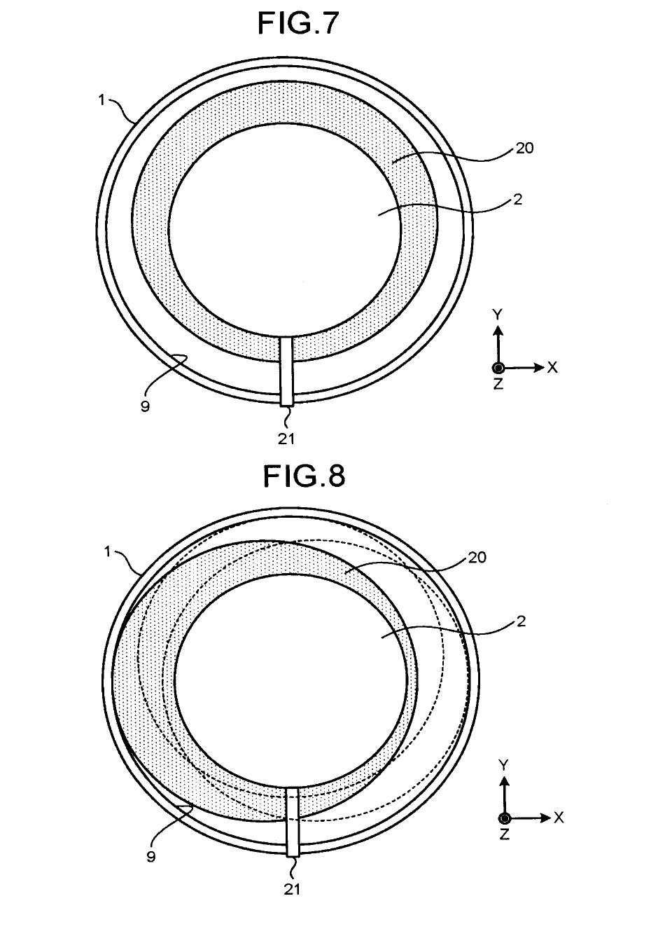

FIG. 7 is a view showing a plan view configuration of the circular disc member shown in FIG. 6. The inner wall 9 of the chamber 1 is connected to the substrate support part 2 by a connecting member 21. The circular disc member 20 has a circular shape larger than the lower surface of the substrate support part 2 on the X-Y plane. The circular disc member 20 includes a portion extending outward from the outer edge of the substrate support part 2, which can come into contact with the process gas flowing between the substrate support part 2 and the inner wall 9. Thus, the circular disc member 20 can hinder the process gas flow by partly closing the opening area between the substrate support part 2 and the inner wall 9.

FIG. 8 is a view for explaining a movement manner of the circular disc member shown in FIG. 7. The circular disc member 20 is freely movable in the X- and Y-directions inside the chamber 1. The plasma processing apparatus can adjust the gap width around the substrate support part 2 by adjusting the position of the circular disc member 20 relative to the substrate support part 2 in the X- and Y-directions. When the circular disc member 20 is moved to the minus side of the X-direction, plasma processing apparatus reduces the gap width on the minus side of the X-direction relative to the substrate support part 2 and increases the gap width on the plus side of the X-direction relative to the substrate support part 2. Thus, the circular disc member 20 can adjust the flow rate balance of the process gas in the X- and Y-directions. Amounts of adjustment of the flow rate in each of the X- and Y-directions are different.

The plasma processing apparatus can make the flow rate of the process gas uniform over the wafer 10 by adjusting the position of the circular disc member 20. Specifically, the circular disc member 20 is moved in a direction in which the etching rate tends to be lower. In this direction relative to the substrate support part 2, when the gap for the process gas to pass through is thereby made narrower, the flow of the process gas becomes slower. Consequently, the residence time of the process gas in the process space is correspondingly prolonged, and the etching progress is thereby promoted.

The circular disc member 20 is not limited to one configured to adjust the flow rate of the process gas in the X-direction and the Y-direction. The circular disc member 20 may have any structure as long as it can adjust the gas flow rate in two or more different directions in parallel with the surface of the wafer 10.

The circular disc member 20 is not limited to one attached to the lower surface of the substrate support part 2. The position of the circular disc member 20 may be suitably altered. The blocking member may be any member other than the circular disc member 20, as long as it can adjust the gap width around the substrate support part 2. The blocking member may be attached to either one of the substrate support part 2 and the inner wall 9.

According to the second embodiment, the semiconductor manufacturing apparatus is configured to move the blocking member. The blocking member can adjust the gas flow rate in two or more different directions in parallel with the surface of the wafer 10. Thus, the semiconductor manufacturing apparatus can make the gas flow rate uniform over the wafer 10 by adjusting the gas flow rate balance in two or more different directions in parallel with the surface of the wafer 10. Consequently, the semiconductor manufacturing apparatus can provide an effect of uniformly processing a processing object.

The semiconductor manufacturing apparatus is not limited to one equipped with both of the surrounding member and the blocking member, each of which serves as a flow rate adjustment part. The semiconductor manufacturing apparatus may be modified to include at least one of the surrounding member and blocking member, each of which serves as a flow rate adjustment part.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor manufacturing apparatus comprising:
a chamber;
a substrate support part provided inside the chamber and configured to support a substrate as a processing object;
a gas supply part configured to supply a gas into a process space above the substrate;
an exhaust port configured to exhaust a gas, which is present inside the chamber, from the chamber; and
a flow rate adjustment part provided inside the chamber and configured to adjust a flow rate of a gas flowing from the process space to the exhaust port,
wherein the flow rate adjustment part is configured to adjust a gas flow rate in two or more different directions in parallel with a surface of the substrate, amounts of adjustment of the flow rate in each of the directions are different.

2. The semiconductor manufacturing apparatus according to claim 1, wherein
the flow rate adjustment part includes a surrounding member that surrounds a periphery of the process space,
the surrounding member is configured to form a gap through which a gas passes to flow from the process space to an outside of the process space, and the surrounding member is divided into a plurality of portions in a direction in parallel with the surface of the substrate, and
the portions formed by division are configured to individually adjust widths of the gap.

3. The semiconductor manufacturing apparatus according to claim 2, wherein
the surrounding member includes a first member set in contact with the gas supply part and a second member that forms the gap between itself and the first member, and
the portions formed by division are configured to individually adjust positions of parts of the first member in a direction perpendicular to the surface of the substrate.

4. The semiconductor manufacturing apparatus according to claim 2, wherein
the surrounding member includes a first member set in contact with the gas supply part and a second member that forms the gap between itself and the first member, and
the portions formed by division are configured to individually adjust positions of parts of the second member in a direction perpendicular to the surface of the substrate.

5. The semiconductor manufacturing apparatus according to claim 2, wherein
the surrounding member includes a first member set in contact with the gas supply part and a second member that forms the gap as a first gap between itself and the first member,
the second member is configured to form a second gap between itself and the substrate support part, and
the portions formed by division are configured to adjust widths of the first gap and widths of the second gap.

6. The semiconductor manufacturing apparatus according to claim 2, wherein
the surrounding member includes a first member set in contact with the gas supply part and a second member that forms the gap between itself and the first member, and
the portions formed by division respectively include adjusting members configured to adjust positions of parts of the first member or the second member in a direction perpendicular to the surface of the substrate.

7. The semiconductor manufacturing apparatus according to claim 1, wherein
the flow rate adjustment part includes a blocking member configured to partly close an opening area between the substrate support part and an inner wall of the chamber around the substrate support part, and
the blocking member is configured to form a gap, through which a gas passes to flow from the process space to the exhaust port, and to adjust a width of the gap.

8. The semiconductor manufacturing apparatus according to claim 7, wherein the blocking member is configured to form the gap between itself and the inner wall, and to adjust a width of the gap by movement in a direction in parallel with the surface of the substrate.

9. The semiconductor manufacturing apparatus according to claim 7, wherein the blocking member is attached to the substrate support part.

10. A semiconductor manufacturing method comprising:
placing a substrate as a processing object onto a substrate support part provided inside a chamber;
supplying a gas from a gas supply part into a process space above the substrate;
exhausting a gas present inside the chamber from an exhaust port formed on the chamber; and
performing adjustment inside the chamber to adjust a flow rate of a gas flowing from the process space to the exhaust port,
wherein the adjustment includes adjusting a gas flow rate in two or more different directions in parallel with a surface of the substrate, amounts of adjustment of the flow rate in each of the directions are different.

11. The semiconductor manufacturing method according to claim 10, wherein
the gas supplied into the process space flows to an outside of the process space by passing through a gap formed by a surrounding member that surrounds a periphery of the process space,
the surrounding member is divided into a plurality of portions, including at least a first portion and a second portion, in a direction in parallel with the surface of the substrate, and
the method comprises using the first portion and the second portion to individually adjust widths of the gap.

12. The semiconductor manufacturing method according to claim 11, wherein
the surrounding member includes a first member set in contact with the gas supply part and a second member that forms the gap between itself and the first member, and
the method comprises using the first portion and the second portion to individually adjust positions of parts of the first member in a direction perpendicular to the surface of the substrate.

13. The semiconductor manufacturing method according to claim 11, wherein
the surrounding member includes a first member set in contact with the gas supply part and a second member that forms the gap between itself and the first member, and
the method comprises using the first portion and the second portion to individually adjust positions of parts of the second member in a direction perpendicular to the surface of the substrate.

14. The semiconductor manufacturing method according to claim 11, wherein
the surrounding member includes a first member set in contact with the gas supply part and a second member that forms the gap as a first gap between itself and the first member,
the second member is configured to form a second gap between itself and the substrate support part, and
the method comprises using the first portion and the second portion to adjust widths of the first gap and widths of the second gap.

15. The semiconductor manufacturing method according to claim 11, wherein
the surrounding member includes a first member set in contact with the gas supply part and a second member that forms the gap between itself and the first member, and
the method comprises using adjusting members respective provided in the first portion and the second portion to individually adjust positions of parts of the first member or the second member in a direction perpendicular to the surface of the substrate.

16. The semiconductor manufacturing method according to claim 10, wherein
a blocking member is configured to partly close an opening area between the substrate support part and an inner wall of the chamber around the substrate support part,
the blocking member is configured to form a gap, through which a gas passes to flow from the process space to the exhaust port, and
the method comprises adjusting a width of the gap.

17. The semiconductor manufacturing method according to claim 16, wherein the method comprises moving the blocking member in a direction in parallel with the surface of the substrate, to adjust a width of the gap formed between the blocking member and the inner wall.

18. A flow rate adjusting mechanism for adjusting a flow rate of a gas flowing from a process space inside a chamber to an exhaust port configured to exhaust a gas present inside the chamber, the flow rate adjusting mechanism comprising:
a surrounding member that surrounds a periphery of the process space along its circumferential direction,
wherein the surrounding member is configured to form a gap communicating the process space with an outside of the process space, and is divided into a plurality of portions along the circumferential direction, and
the portions formed by division are configured to individually adjust widths of the gap.

19. The flow rate adjusting mechanism according to claim 18, wherein the portions formed by division respectively include adjusting members configured to adjust widths of the gap.

20. The flow rate adjusting mechanism according to claim 19, wherein
the surrounding member includes a first member and a second member that forms the gap between itself and the first member, and
the adjusting members are configured to individually adjust positional relationships between the first member the second member at the portions formed by division.
